(19) United States
(12) Patent Application Publication
(10) Pub. No.: US 2022/0029442 A1
(43) Pub. Date: Jan. 27, 2022

(54) ASSEMBLY FOR SWITCHING A HIGH-VOLTAGE BATTERY IN A VEHICLE

(71) Applicant: Robert Bosch GmbH, Stuttgart (DE)

(72) Inventors: Andreas Mittag, Markgroeningen (DE); Daniel Raichle, Vaihingen (DE); Hans Geyer, Pfedelbach-Untersteinbach (DE); Marcel Maur, Asperg (DE); Martin Trunk, Neuenstadt (DE); Klaus-Juergen Wald, Calw (DE)

(21) Appl. No.: 17/312,300

(22) PCT Filed: Dec. 6, 2019
(86) PCT No.: PCT/EP2019/083958

§ 371 Date: Jun. 9, 2021

(30) Foreign Application Priority Data
Dec. 11, 2018 (DE) 10 2018 221 426.3

(51) Int. Cl. H02J 7/00; B60R 16/03; H03K 17/687; H03K 17/12

(52) U.S. Cl. CPC H02J 7/00711; H02J 7/0063; H02J 7/0031; H02J 7/00304; B60L 2270/20; H03K 17/687; H03K 17/122; H02J 2310/40; B60R 16/03

(57) ABSTRACT

The invention relates to a circuit assembly, to a system and to a method for switching a high-voltage battery (201) and to a vehicle having such a circuit assembly and such a system. The circuit assembly comprises a transistor for conducting a current from the battery (201) to a load and comprises a diode (202) for conducting a return current into the battery (201). The circuit assembly is configured to provide a pre-charging current by means of the pulsed switching of the transistor (203).

The present invention relates to an assembly for switching a high-voltage battery in a vehicle, a system having a high-voltage battery, a circuit assembly and a consumer circuit, and a vehicle which has such an assembly and such a system. In addition, the invention relates to a method for connecting and a method for disconnecting a battery.

The term “switching a battery”, i.e. switching a battery on or off, is used here to mean the connection or disconnection of the battery to or from a consumer circuit. Similarly, connection and disconnection of the battery are intended to mean connection to and disconnection from a consumer circuit. A consumer circuit has, for example, an electric motor, control circuits, voltage transformers and further consumers in the vehicle and typically has capacitances and inductances.

High-voltage batteries in vehicles are generally mechanically or electromechanically disconnected or connected to the consumer circuit via switches. The switches are arranged both at the positive terminal and at the negative terminal of the battery. Typically, relays are used as switches. Since a connection by means of a relay is produced without any directional sense, the circuit is provided with two paths, each having a switch, at the positive terminal. In this case, one path is used for precharging the capacitances of the downstream circuit, while the other is provided for the time period after the precharging. Therefore, in total three relays are required: one for the precharging path and one for the switch-on path at the positive terminal and one at the negative terminal. The connections are in this case bidirectional, i.e. the current can flow in each path, both towards the battery or away from the battery and towards the consumer circuit.

The precharging circuit is used for limiting the switch-on current which is produced, for example, in the case of high-capacitance consumers when a high voltage is applied. For this purpose, a resistor is used, for example, which is arranged in the precharging path. As soon as the capacitances are charged, there is a switchover to the other path without the resistor, with the result that no losses and no heat occur at the resistor as time goes on.

The driving of three relays is complex. In addition, relays are susceptible to wear, and the precharging current cannot be regulated.

It is therefore the object of the present invention to provide a cost-effective and efficient circuit assembly for switching a high-voltage battery.

### DISCLOSURE OF THE INVENTION

The object is achieved by a circuit assembly, a system, a motor vehicle and methods as claimed in the independent claims. The respectively back-referenced dependent claims reflect advantageous developments of the invention.

In accordance with one aspect, a circuit assembly for switching a high-voltage battery is provided. The circuit assembly has a precharging circuit, which is designed for connection to a first terminal of the high-voltage battery and for precharging a consumer, having a transistor for conducting a current from the battery to the consumer and a diode arranged back-to-back in parallel with the transistor for conducting a return current into the battery.

With this assembly, electronic switching is enabled, with the result that energy is transported from the battery to a consumer via the drain-source path of the transistor. Both the switching-on and the switching-off are implemented without any mechanical components. Furthermore, the diode enables a return flow of energy from the consumer circuit, i.e. from the circuit connected to the circuit assembly, into the battery. Such a return flow can originate, for example, from a further battery in the connected circuit, from inductions in the consumer circuit or from a charging operation.

In accordance with one exemplary embodiment, the transistor is a silicon carbide MOSFET (metal-oxide-semiconductor field-effect transistor) semiconductor (SiC MOSFET), and the diode is integrated in the silicon carbide MOSFET semiconductor. SiC MOSFETs have a relatively high degree of robustness and are additionally well suited to high switching frequencies. Furthermore, a SiC MOSFET has considerably lower power losses. Reduced power losses result in a higher efficiency and in lower system costs and sizes owing to the decreased amount of cooling complexity involved.

In accordance with one exemplary embodiment, the transistor is configured to switch in pulsed fashion during switching-on of the consumer during a precharging phase.

In this case, the precharging phase can in particular be a phase in which the capacitances of the consumer circuit are charged and can last until said capacitances are sufficiently charged. Sufficiently in this case means that no impermissibly high currents flow when the transistor is permanently switched on, which corresponds to a second phase. In this case, a safety margin can be taken into consideration.

Owing to the pulses, the capacitances are charged gradually in a defined manner, and therefore a low and monitored current is output to the consumer circuit virtually without losses for precharging. As a result, a resistor for precharging becomes superfluous. The driving of a second switch, such as, for example, a relay or switchover between two switches can be dispensed with. Therefore, the circuit assembly can replace, for example, two paths, i.e. both the direct connection and the precharging path at the positive terminal of the battery, and additionally enables an energy flow to the battery. If a SiC MOSFET with an integrated inverse diode is used, only one component is necessary for this. Furthermore, the good switchability of SiC MOSFETs in particular in the pulsed operating mode for precharging is advantageous.

In accordance with one exemplary embodiment, the circuit assembly has a switch, which is designed for connection to a second terminal of the high-voltage battery. The switch is implemented, for example, by a relay. As a result, the return current flow can be prevented, if necessary.

In accordance with one aspect, a system for switching a high-voltage battery is provided. The system has a circuit assembly as described above, a high-voltage battery, and a consumer circuit, wherein the first terminal of the high-voltage battery is connectable to the precharging circuit, and wherein the precharging circuit is connectable to a positive line of the consumer circuit. The consumer circuit has capacitive properties.

This aspect therefore includes the circuit assembly with the battery on one circuit assembly side and the consumer circuit on the other circuit assembly side, wherein the circuit assembly represents the connecting element between the battery and the consumer circuit. In particular, the circuit assembly is connected to the positive terminal of the battery on one side and the positive supply line of the consumer circuit. The circuit assembly in particular takes account of the capacitive properties of the consumer circuit by virtue of the precharging circuit.

In accordance with one embodiment, the second terminal of the high-voltage battery in the system is connectable to a relay, and the relay is connectable to a negative line of the consumer circuit. The second terminal can in particular be the negative terminal of the battery, which can be connected, via the relay, to the negative line of the consumer circuit. By virtue of this relay, the circuit via the battery, i.e. the current flow from or to the battery, can be disconnected.

In accordance with one aspect, in a method for connecting a high-voltage battery in a vehicle with an assembly as described above, in a first phase, during the connection the transistor is switched in pulsed fashion, and, in a second phase, during the connection the transistor is switched on. In this case, “switched on” is understood to mean that the transistor is switched so as to be conducting. By virtue of the pulsed switching, in the first phase the precharging is enabled. In the second phase, the battery is connected to the consumer circuit via the conducting transistor.

In accordance with one embodiment, the first phase is concluded when the consumer is approximately or completely charged. The purpose of the first phase, in which the current flows in pulsed fashion via the transistors, is that the battery and the electronic component parts, including the lines, are not overloaded by the current flow to the capacitances. Secondly, the current flow during charging of a capacitance asymptotically approaches zero. Therefore, the capacitive consumer should be charged in pulsed fashion until it is ensured that no overloads occur, wherein this is not necessarily at 100% charge.

In accordance with one aspect, in a method for disconnecting a high-voltage battery in a vehicle having an assembly as described above, the transistor is turned off, and a return current is conducted via the diode to the battery.

In accordance with one aspect of the invention, a vehicle is provided, which has a circuit assembly as described above. In this case, a vehicle can be, for example, an electric vehicle, a vehicle with a hybrid drive, a heavy goods vehicle or a bus. Furthermore, the vehicles can be operated with overhead lines or on rails. Within the further meaning, vehicles are also understood to mean electrically driven boats or aircraft or airplanes.

Exemplary embodiments of the invention are illustrated in the drawings and will be explained in more detail in the description below. In the drawings:

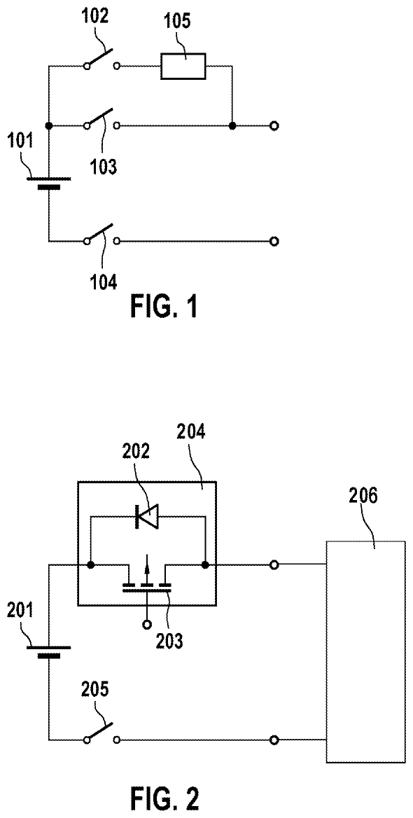

FIG. 1 shows a circuit assembly for connecting and disconnecting a high-voltage battery,

FIG. 2 shows a circuit assembly and a system for connecting and disconnecting a high-voltage battery in accordance with one exemplary embodiment,

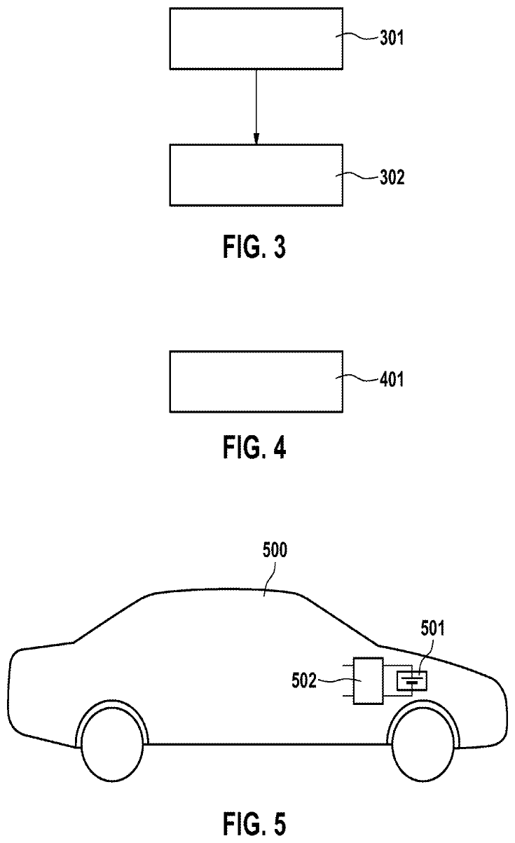

FIG. 3 shows a block circuit diagram of a method for connecting a high-voltage battery in accordance with one exemplary embodiment,

FIG. 4 shows a block circuit diagram of a method for disconnecting a high-voltage battery in accordance with one exemplary embodiment,

FIG. 5 shows a vehicle having a circuit assembly or a system in accordance with one exemplary embodiment.

FIG. 1 shows a typical circuit assembly for connecting and disconnecting a high-voltage battery 101. The circuit assembly has three switches 102, 103, 104. In order to connect the battery, first the switch 104 at the negative terminal and the switch 102 at the positive terminal are closed. The battery 101 can then output current via the resistor 105 to the consumer circuit, wherein precharging of the capacitances of the consumer circuit takes place by virtue of the resistor 105. After the precharging, the precharging branch 102, 105 is bypassed by closing of the switch 103. On disconnection of the battery 101, first the switch 103 is opened. The return current can flow via the resistor 105 and the closed switch 102 to the battery 101. For final disconnection, the switches 102 and 104 are opened.

FIG. 2 shows a circuit assembly and a system for connecting and disconnecting a high-voltage battery 201 in accordance with one exemplary embodiment of the invention. The circuit assembly has a non-electronic switch, for example, a mechanical switch or a relay 205, and an electronic switch, for example, a transistor 203. In one embodiment, the electronic switch 203 is integrated together with a diode 202 in a component, for example in a SiC MOSFET 204. However, other high-power transistors can also be used, such as, for example, IGBTs or suitable field-effect transistor variants. The integrated diode 202 is, for example, a diode which, owing to its forward direction opposite the forward direction of the transistor, is also referred to as an inverse diode or as a body diode.

In general, the switch 205 can be closed, but it can be opened for completely disconnecting the battery 201, if necessary. If the battery 201 is connected, a pulsed signal is applied to the gate of the transistor 203, with the result that the capacitances of the consumer circuit are precharged with short current bursts. The effective current intensity can be controlled by the pulse widths until the capacitances are charged. It is therefore possible, for example, to regulate the current intensity at the start by short pulses, and to extend the pulses gradually until there is a steady signal, with the result that, after the precharging phase, the transistor is permanently switched on, i.e. when there is no longer a precharging current flowing or only a low precharging current flows. Alternatively, the current could also be controlled via an analog gate voltage. In this case, a drive circuit for the gate voltage is required, which initially severely limits the battery current during switching-on and then gradually reduces the limitation.

In order to disconnect the high-voltage battery 201, the transistor 203 is turned off via the gate voltage. The return current can now flow via the integrated diode 202 towards the battery 201. The battery 201 can additionally be mechanically disconnected via the switch 205. This can be used, for example, when it is desirable for there to be no return current flow into the battery.

The system for switching a high-voltage battery, in one embodiment, has a circuit assembly having at least one precharging circuit 204, a high-voltage battery 201 and a consumer circuit 206 having capacitive properties. The circuit assembly can furthermore have the switch 205.

FIG. 3 shows a block circuit diagram of a method for connecting a high-voltage battery in accordance with one exemplary embodiment of the invention. The method is performed using the assembly described in FIG. 2. In a first phase 301, during the connection the transistor 203 is switched in pulsed fashion. In this phase, the capacitances of the consumer circuit are precharged. In a second phase 302, during the connection the transistor 203 is switched on. This corresponds to the normal operating mode with the consumer connected, such as, for example, a motor or further circuits such as voltage transformers and further consumers.

FIG. 4 shows a block circuit diagram of a method for disconnecting a high-voltage battery 201 in accordance with one exemplary embodiment of the invention. The method is performed using the assembly described in FIG. 2. For the disconnection, the transistor 203 is turned off only in 401. The return current can flow via the diode 202 to the battery. Here, the advantage of the assembly is particularly significant since no further switching or no further method steps are required.

FIG. 5 shows a vehicle 500 in accordance with one embodiment of the invention. The vehicle 500 has a battery 501 and a circuit 502, which corresponds to the circuit assembly shown in FIG. 2, and contains a transistor 203 as described above, having a diode 202. In one embodiment, the circuit assembly furthermore contains a mechanical or electromechanical switch, such as, for example, a relay 205.

The high-voltage battery 201 can be located at a suitable position in the vehicle, such as, for example, in the vicinity of the front axle or the rear axle. The circuit assembly is preferably located in the vicinity of the battery, with the result that the potential-carrying lines at the terminals of the battery are short. In general, the circuit can also be arranged so as to be physically remote from the battery.

1. A circuit assembly for switching a high-voltage battery (201), having:
a precharging circuit (204) configured for connection to a first terminal of the high-voltage battery (201) and for precharging a consumer, the consumer having a transistor (203) for conducting a current from the battery (201) to the consumer and a diode (202) arranged back-to-back in parallel with the transistor for conducting a return current into the battery (201).

2. The circuit assembly as claimed in claim 1, wherein the transistor (203) is a silicon carbide MOSFET semiconductor, and the diode (202) is integrated in the silicon carbide MOSFET semiconductor (203).

3. The circuit assembly as claimed in claim 1, wherein the transistor (203) is configured to switch in pulsed fashion on connection of the battery (201) during a precharging phase.

4. The circuit assembly as claimed in claim 1, further having:
a relay (205), designed for connection to a second terminal of the high-voltage battery (201).

5. A system (201, 204, 206) for switching a high-voltage battery (201), having:
a circuit assembly as claimed in claim 1,
a high-voltage battery (201), and
a consumer circuit (206), wherein
the first terminal of the high-voltage battery (201) is connectable to the precharging circuit (204),
the precharging circuit (204) is connectable to a positive line of the consumer circuit (206), and wherein
the consumer circuit (206) has capacitive properties.

6. The system (201, 204, 206) as claimed in claim 5, wherein the second terminal of the high-voltage battery (201) is connectable to a relay (205), and the relay (205) is connectable to a negative line of the consumer circuit (206).

7. A motor vehicle (500), having a circuit assembly comprising:
a precharging circuit (204) configured for connection to a first terminal of the high-voltage battery (201) and for precharging a consumer, the consumer having a transistor (203) for conducting a current from the battery (201) to the consumer and a diode (202) arranged back-to-back in parallel with the transistor for conducting a return current into the battery (201).

8. A method (301, 302) for connecting a high-voltage battery (201) to a consumer circuit (206) in a motor vehicle (500) by means of a circuit assembly having a precharging circuit (204) configured for connection to a first terminal of the high-voltage battery (201) and for precharging a consumer, the consumer having a transistor (203) for conducting a current from the battery (201) to the consumer and a diode (202) arranged back-to-back in parallel with the transistor for conducting a return current into the battery (201), the method comprising:
in a first phase (301), during the connection, switching the transistor (203) in pulsed fashion, and,
in a second phase (302), during the connection, switching the transistor (203) on.

9. The method (301, 302) as claimed in claim 8, wherein the first phase (301) is concluded when the consumer (206) is approximately or completely charged.

10. A method (401) for disconnecting a high-voltage battery (201) in a motor vehicle (500) having a circuit assembly having a precharging circuit (204) configured for connection to a first terminal of the high-voltage battery (201) and for precharging a consumer, the consumer having a transistor (203) for conducting a current from the battery (201) to the consumer and a diode (202) arranged back-to-back in parallel with the transistor for conducting a return current into the battery (201), wherein the transistor (203) is turned off, and a return current is conducted via the diode (202) to the battery (201).
